(19) United States
(12) Patent Application Publication
(10) Pub. No.: US 2009/0273054 A1
(43) Pub. Date: Nov. 5, 2009

(54) Non-volatile memory device and method of fabricating the same

(75) Inventors: Suk-pil Kim, Yongin-si (KR); Won-joo Kim, Hwaseong-si (KR); Seung-hoon Lee, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/382,106

(22) Filed: Mar. 9, 2009

(30) Foreign Application Priority Data
May 1, 2008 (KR) 10-2008-0041052

(51) Int. Cl. H01L 29/68

(52) U.S. Cl. 257/529; 257/530; 257/E29.17

(57) ABSTRACT

A non-volatile memory device and methods of fabricating the device according to example embodiments involve a stacked layer structure. The non-volatile memory device may include at least one first horizontal electrode including a first sidewall and a second sidewall; at least one second horizontal electrode including a third sidewall and a fourth sidewall; wherein the third sidewall may be disposed to face the first sidewall; at least one vertical electrode may be interposed between the first sidewall and the third sidewall, in such a way as to cross or intersect each of the at least one first and second horizontal electrodes, and; at least one data storage layer that may be capable of locally storing a change of electrical resistance may be interposed where the at least one first horizontal electrode and the at least one vertical electrode cross or intersect and where the at least one horizontal electrode and the at least one vertical electrodes cross or intersect.

### PRIORITY STATEMENT

This application claims priority under 35 U.S.C. §119 to Korean Patent Application No. 10-2008-0041052, filed on Jun. 5, 2008, in the Korean Intellectual Property Office (KIPO), the entire contents of which is incorporated herein by reference.

### BACKGROUND

1. Field

Example embodiments are directed to a semiconductor device and a method of fabricating the device, and for example, to a non-volatile memory device using a data storage layer that is capable of storing a change of its own electrical resistance, and methods of fabricating the device.

2. Description of the Related Art

Although the size of semiconductor products has decreased, with a corresponding improvement in overall performance, the volume of data that semiconductor products are required to process has continually increased. As a result, it has been necessary to continually improve the operating speed and integration density of non-volatile memory devices used in semiconductor products. This, in turn, has led to non-volatile memory devices with a multi-layer structure becoming more advantageous than non-volatile memory devices having a single-layer structure, due to their higher integration potential.

By using a multi-layer structure, memory cells may be stacked vertically while occupying about the same horizontal space as a single-layer structure. However, in a non-volatile memory device of this type, connecting and selecting memory cells in each of the layers is a difficult task. Additionally, as the number of stacked layers increases, the number of manufacturing steps also increases, with a commensurate increase in the overall cost.

### SUMMARY

Example embodiments relate to a nonvolatile memory device using a layer structure, including a stacked layer structure, and methods of fabricating the device.

According to example embodiments, a non-volatile memory device may include: one or more first horizontal electrodes having a first sidewall and a second sidewall; one or more second horizontal electrodes having a third sidewall and a fourth sidewall; wherein the third sidewall may be disposed to face the first sidewall of the first horizontal electrode; one or more vertical electrodes, where a vertical electrode may be interposed between the first sidewall of one or more first horizontal electrodes and the third sidewall of one or more of the second horizontal electrodes; the vertical electrode may cross or intersect one or more first and second horizontal electrodes; one or more data storage layers, where a data storage layer may be interposed between where one or more first horizontal electrodes and one or more vertical electrodes cross or intersect and where one or more second horizontal electrodes and one or more vertical electrodes cross or intersect; and where the data storage layer may be capable of locally storing a change of electrical resistance.

A vertical electrode may include a plurality of vertical electrodes disposed apart from each other. Furthermore, a data storage layer may be disposed to correspondingly fill the areas around the plurality of vertical electrodes.

According to example embodiments, the first and second horizontal electrodes may include a first conductive semiconductor, and the vertical electrode may include a second conductive semiconductor having an opposite conductive type from the first conductive semiconductor.

According to example embodiments, the first horizontal electrode may include a plurality of first horizontal electrodes, the second horizontal electrode may include a plurality of second horizontal electrodes interposed alternately with the plurality of the first horizontal electrodes, the vertical electrode may include a plurality of vertical electrodes disposed in a plurality of rows between the first sidewalls of the plurality of the first horizontal electrodes and the third sidewalls of the plurality of the second horizontal electrodes.

According to example embodiments, a non-volatile memory device may include a first wordline electrically connected to the plurality of first horizontal electrodes; and a second wordline electrically connected to the plurality of second horizontal electrodes. The first wordline may be connected to one end of the plurality of first horizontal electrodes, and the second wordline may be connected to one end of the plurality of second horizontal electrodes and may be disposed at a side opposite to the first wordline.

According to example embodiments, one or more first horizontal electrodes may include a plurality of first horizontal electrodes stacked in a plurality of layers, and one or more second horizontal electrodes may include a plurality of second horizontal electrodes stacked in a plurality of layers and facing the plurality of first horizontal electrodes. One or more vertical electrodes and/or one or more data storage layers may vertically extend across the plurality of first and second horizontal electrodes.

According to example embodiments, a method of fabricating a non-volatile memory device may be provided, the method including forming one or more first horizontal electrodes having a first sidewall and a second sidewall; forming one or more second horizontal electrodes having a third sidewall and a fourth sidewall, wherein the third sidewall faces the first sidewall of the first horizontal electrodes; forming one or more data storage layers capable of locally storing a change of electrical resistance on the first sidewall of one or more first horizontal electrodes and on the third sidewall of one or more second horizontal electrodes; and forming one or more vertical electrodes disposed on the data storage layers to cross or intersect one or more first and second horizontal electrodes.

According to example embodiments, the method may include stacking one or more first electrode layers and one or more insulation layers alternately; forming a plurality of trenches in one or more of the first electrode layers; and forming one or more data storage layers, wherein one or more first horizontal electrodes and one or more second horizontal electrodes may include portions of one or more first electrode layers defined by the plurality of trenches.

According to example embodiments, the method may include forming a first wordline and a second wordline using portions of one or,more first electrode layers located at both ends of the plurality of trenches; and separating the plurality of second horizontal electrodes and the first wordline and separating the plurality of first horizontal electrodes and the second wordline.

### BRIEF DESCRIPTION OF THE DRAWINGS

Example embodiments will be more clearly understood from the following brief description taken in conjunction with the accompanying drawings. FIGS. 1-13 represent non-limiting, example embodiments as described herein.

FIG. 1-2 are perspective views of a non-volatile memory device according to example embodiments;

FIG. 3 is a cross-sectional view obtained along line III-III′ of FIG. 2;

FIG. 4 is a perspective view of a non-volatile memory device according to example embodiments;

FIGS. 5-10 are perspective views for explaining a method of fabricating the non-volatile memory device of FIG. 2, according to example embodiments; and

FIGS. 11-13 are perspective views showing a method of fabricating the non-volatile memory device of FIG. 4, according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

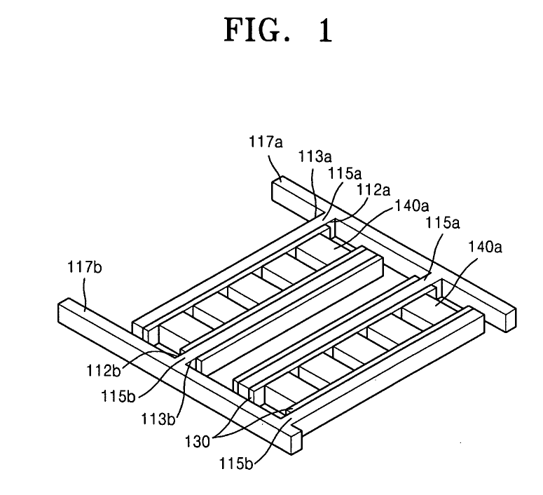

Example embodiments will now be described with reference to FIG. 1. In example embodiments, one or more first horizontal electrodes 115a and one or more second horizontal electrodes 115b may be present. However, for illustrative purposes, as shown in FIG. 1, a plurality of the first horizontal electrodes 115a and a plurality of the second horizontal electrodes 115b are arranged to face each other. The number of first horizontal electrodes 115a and the number of second horizontal electrodes 115b, shown in FIG. 1, are merely an example, and example embodiments are not limited thereto. Thus, the number of first and second horizontal electrodes 115a and 115b may vary according to the capacity of the non-volatile memory device.

The first horizontal electrodes 115a and the second horizontal electrodes 115b may be alternately arranged extending parallel to each other. However, the arrangement is merely an example, and example embodiments are not limited thereto. For example, the first horizontal electrodes 115a and the second horizontal electrodes 115b may be arranged in a non-parallel manner as long as the first horizontal electrodes 115a and the second horizontal electrodes 115b do not contact each other.

The horizontal electrodes 115a may include a first sidewall 112a and a second sidewall 113a, that may be opposite to each other, and each of the second horizontal electrodes 115b may include a third sidewall 112b and a fourth sidewall 113b, which may be opposite to each other. For example, the first horizontal electrodes 115a and the second horizontal electrodes 115b may be arranged such that the first sidewall 112a and the third sidewall 112b face each other and a second sidewall 113a and the fourth sidewall 113b face each other.

One vertical electrode 140a may be interposed between every two of the adjacent first and second horizontal electrodes 115a and 115b to cross the first and second horizontal electrodes 115a and 115b. However, as shown in FIG. 1, vertical electrodes 140a may be arranged apart from each other in a row between every two of the adjacent first and second horizontal electrodes 115a and 115b. For example, the vertical electrodes 140a may be arranged in a plurality of rows between the first and third sidewalls 112a and 112b such that the vertical electrodes 140a extend longer in a direction perpendicular to the extending direction of the adjacent first and second horizontal electrodes 115a and 115b. According to example embodiments, the vertical electrodes 140a may not be interposed between the second and fourth sidewalls 113a and 113b. The vertical electrodes 140a may be arranged in a row between every two of the adjacent first and second horizontal electrodes 115a and 115b. However, this configuration is merely an example for illustration purposes, and example embodiments may not be limited as described and may include various electrode configurations.

The number of vertical electrodes 140a may be selected according to a capacity of the non-volatile memory device. The number of vertical electrodes 140a may also be selected according to the number and length of the first and second horizontal electrodes 115a and 115b. Therefore, the number of vertical electrodes 140a shown in FIG. 1 is merely an example, and example embodiments are not limited thereto.

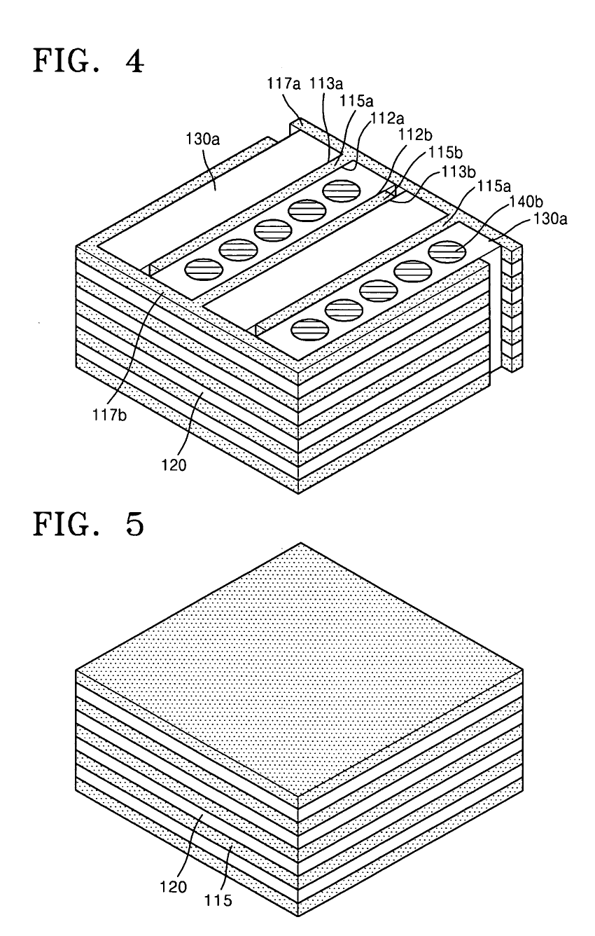

Although the vertical electrodes 140a are shown as rectangular pillars, example embodiments are not limited to that shape. For example, the vertical electrodes 140a may have a polygonal shape. As another example, the shape of the vertical electrodes 140a may be cylindrical, as shown in FIG. 4.

One or more data storage layers 130 may be interposed where the first horizontal electrodes 115a and the vertical electrodes 140a cross, and/or where the second horizontal electrodes 115b and the vertical electrodes 140a cross. For example, as shown in FIG. 1, the data storage layers 130 may be arranged to extend along one or more of the first and third sidewalls 112a and 112b. The shape of the data storage layers 130 shown in FIG. 1 is merely an example and may vary. For example, the data storage layers 130 may be shaped as patterns such that the data storage layers 130 are confined to where the horizontal electrodes 115a and the vertical electrodes 140a intersect.

The data storage layers 130 may control flow of electrical current between the first and the second horizontal electrodes 115a and 115b and the vertical electrodes 140a. For example, the data storage layers 130 may have variably resistive characteristics and locally store a change of electrical resistance. Variable resistive characteristics of the data storage layers 130 may include, for example, a high resistance state, a low resistance state, or an insulator state. However, there may be many states, for example, where the material resistance follows a hysteresis. The resistive characteristics may vary according to an applied signal, such as an electrical signal (e.g., current or voltage). The variable resistive characteristics may be used for storing data in a non-volatile memory device.

Variably resistive data storage layers 130 may include an anti-fuse, for example, a phase-change resistor or a variable resistor. The non-volatile memory device may operate as a phase-change random access memory (PRAM) or a resistance random access memory (RRAM). For example, a phase-change resistor may include a chalcogenide compound, (e.g., GST(GeSbₓTe_{y})). The phase-change resistor may have resistance states according to a crystalline state of the phase-change resistor. A variable resistor may be differentiated from a phase-change resistor because the electrical resistance of the variable resistor may change without a change of phase. A variable resistor may include but is not limited to NiO, Nb₂O₅, or ZnO.

The data storage layers 130 may include a fuse, for example, a dielectric breakdown material. The data storage layers 130 may include a dielectric material (e.g., oxide) in which the dielectric characteristic may be broken down according to an applied voltage. Because such dielectric breakdown material does not recover dielectric characteristics, the non-volatile memory device may be used as a one-time program (OTP) memory. Despite their shortcomings, OTP memory devices may be used in products requiring a very large memory capacity.

If the data storage layers 130 are conductive, the first and second horizontal electrodes 115a and 115b, and the vertical electrodes 140a, may form a diode coupling that exhibits a rectification characteristic. For example, the first and second horizontal electrodes 115a and 115b may include a first type of conductive semiconductor, whereas the vertical electrodes 140a may include a second type of conductive semiconductor, the second type being a conductive type opposite to the first conductive type. For example, the first conductive type and the second conductive type may be n-type and p-type, respectively, or vice versa.

A first wordline 117a may be arranged to electrically connect to the first horizontal electrodes 115a, whereas a second wordline 117b may be arranged to electrically connect to the second horizontal electrodes 115b. The first wordline 117a and the second wordline 117b may be arranged at sides opposite from each other, across the first and second horizontal electrodes 115a and 115b. For example, the first wordline 117a may be connected to one end of the first horizontal electrodes 115a, whereas the second wordline 117b may be connected to one end of the second horizontal electrodes 115b.

In the non-volatile memory device according to the example embodiments, one of the first and second horizontal electrodes 115a and 115b, one of the vertical electrodes 140a, and the portion of the data storage layers 130 in between, may form a memory cell. Access to the first and second horizontal electrodes 115a and 115b may be carried out through the first wordline 117a or the second wordline 117b. Therefore, access to a memory cell may be carried out by selecting one of the first and second wordlines 117a and 117b and one of the vertical electrodes 140a.

A memory cell may be programmed by applying a programming signal to one of the first or second wordlines 117a or 117b and one of the vertical electrodes 140a. For example, the programming signal may be a voltage or a current. The electrical resistance in the data storage layer 130 may change locally due to a concentration of electrical current at a crosspoint between the selected vertical electrode 140a and the selected first or second horizontal electrode 115a or 115b. Therefore, in the data storage layers 130, programming may be performed locally.

A memory cell may be read by applying a read signal to one of the first and second wordlines 117a and 117b and one of the vertical electrodes 140a. For example, the read signal may be a voltage or a current. A local change of electrical resistance in the data storage layer 130 may be measured in order to determine the state to which the device was programmed. For example, the current level may used to determine the state.

Example embodiments will be described with reference to FIG. 1. In example embodiments, the vertical electrodes 140a may be coupled to the first side wall 112a and the third sidewall 112b of the adjacent first and second horizontal electrodes 115a and 115b. An accumulation of stress within a memory cell may be reduced as opposed to a configuration in which the vertical electrodes 140a may be coupled to the first through fourth sidewalls 112a through 113b of the adjacent first and second electrodes 115a and 115b. Thus, reliability of the non-volatile memory device may be improved.

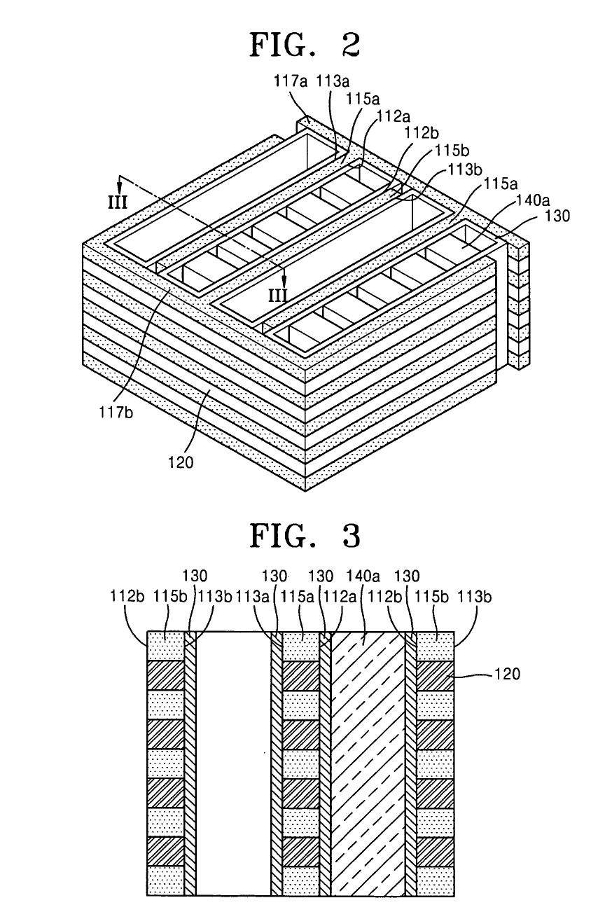

Example embodiments will be described with reference to FIGS. 1-3. A detailed description of FIG. 1 was previously given and will not be repeated. Referring to FIGS. 2 and 3, a plurality of non-volatile memory devices, each structured as shown in FIG. 1, may be stacked in a plurality of layers. For example, a plurality of the first and second horizontal electrodes 115a and 115b may be stacked in a plurality of layers by interposing insulation layers 120 between adjacent layers. Similarly, a plurality of the first and second wordlines 117a and 117b may be stacked in a plurality of layers by interposing insulation layers 120 between adjacent layers. Accordingly, the plurality of first and second horizontal electrodes 115a and 115b in adjacent layers may be separated. Similarly, the plurality of first and second wordlines 117a and 117b in adjacent layers maybe separated.

The vertical electrodes 140a may extend vertically through the stacked layers of the first and second horizontal electrodes 115a and 115b. For example, the vertical electrodes 140a may be positioned vertically between the stacked first sidewalls 112a and the stacked third sidewalls 112b. Thus the vertical electrodes 140a may be shared commonly by the stack of first and second horizontal electrodes 115a and 115b.

The data storage layers 130 may extend vertically along sidewalls of the first and second horizontal electrodes 115a and 115b. For example, the data storage layers 130 may further extend onto sidewalls of the first and second wordlines 117a and 117b and fill the areas around the vertical electrodes 140a disposed at each row. As stated above, the data storage layers 130 may locally store electrical resistance, and thus the data storage layers 130 may be shared in various forms by the memory cells.

Operation of the non-volatile memory device according to example embodiments may be extrapolated from the operation of the non-volatile memory device of FIG. 1.

The capacity of the non-volatile memory device according to example embodiments may be increased by increasing the number of memory cells. For example, the number of first and second horizontal electrodes 115a and 115b or the number of stacked layers. Therefore, the non-volatile memory device according to example embodiments may have a much higher integration in the same area as compared to a conventional non-volatile memory device, and thus may be suitable as a high-capacity and high-integration product.

Example embodiments will be described with reference to FIGS. 1-4. A detailed description of FIGS. 1-3 were previously given and will not be repeated. The non-volatile memory device according to example embodiments may be a modified form of the non-volatile memory device of FIG. 2.

Referring to FIG. 4, vertical electrodes 140b may be cylindrically shaped, and data storage layers 130a may be arranged to correspondingly fill the areas around the vertical electrodes 140b. Therefore, the data storage layers 130a may fill gaps between the first and second horizontal electrodes 115a and 115b, and the vertical electrodes 140b may be recessed into the data storage layers 130a.

In the non-volatile memory device according to example embodiments, the change of electrical resistance in the data storage layers 130a may locally occur at a cross point between the first and second horizontal electrodes 115a and 115b and the vertical electrodes 140b. Therefore, the operation of the non-volatile memory device according to example embodiments is, for the most part, the same as the operation of the non-volatile memory device of FIG. 2.

Example embodiments will be described with reference to FIGS. 2 and 5-10, with FIGS. 5-10 showing a method of fabricating the non-volatile memory device of FIG. 2. A detailed description of FIG. 2 was previously given and will not be repeated. Referring to FIG. 5, one or more first electrode layers 115 may be stacked on one or more insulation layers 120. For illustrative purposes, as shown in FIG. 5, a plurality of the first electrode layers 115 and a plurality of the insulation layers 120 may be alternately stacked. The first electrode layers 115 may be formed as semiconductor layers, for example, epitaxial layers or poly-silicon layers. The first electrode layers 115 may be doped with first conductive type impurities.

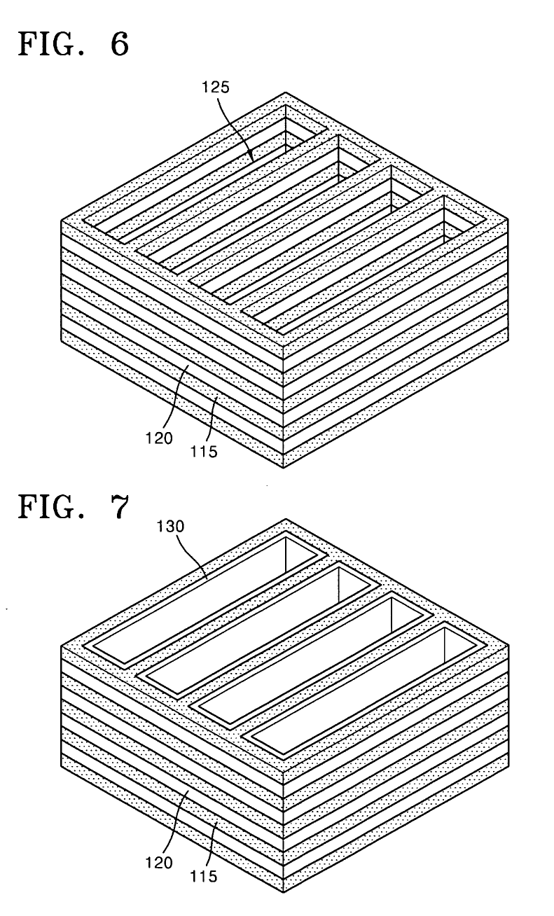

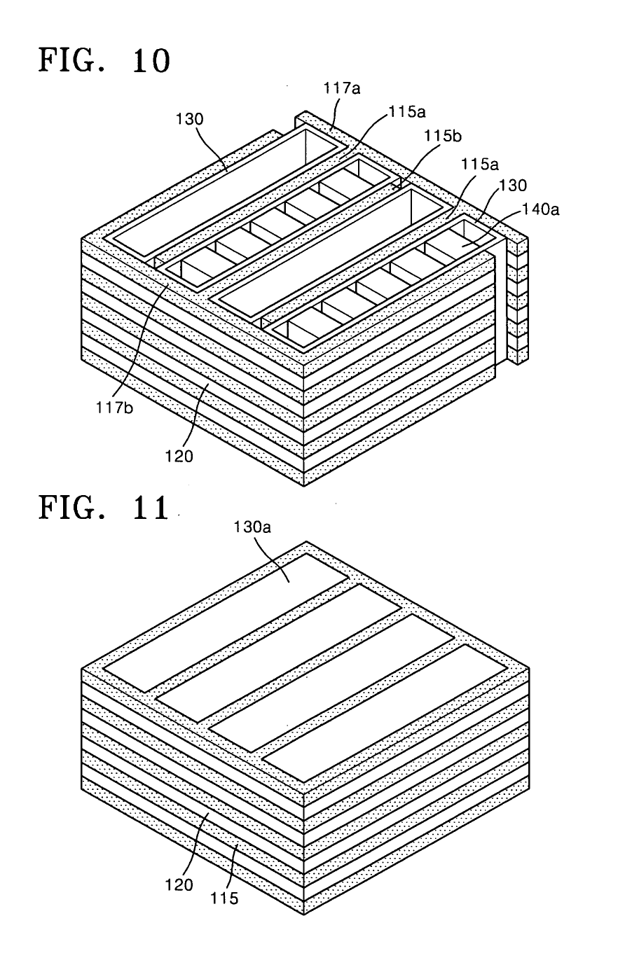

Referring to FIG. 6, a plurality of trenches 125 may be formed in the first electrode layers 115 and the insulation layers 120. Portions of the first electrode layers 115 extending as the sidewalls of the trenches 125 in a plurality of rows may be the horizontal electrodes 115a and 115b in FIG. 10. Portions of the first electrode layers 115 arranged as ends of the trenches 125 may be the first and second wordlines 117a and 117b in FIG. 10. Therefore, the number and shape of the trenches 125 may be formed according to the widths and number of first and second horizontal electrodes 115a and 115b and first and second wordlines 117a and 117b.

Referring to FIG. 7, the data storage layers 130 may be formed correspondingly in the trenches 125. The data storage layers 130 extend vertically across sidewalls of the first electrode layers 115 and may have a thickness such that the trenches 125 are not filled. The data storage layers 130 may, for example, be a material forming a fuse or an anti-fuse.

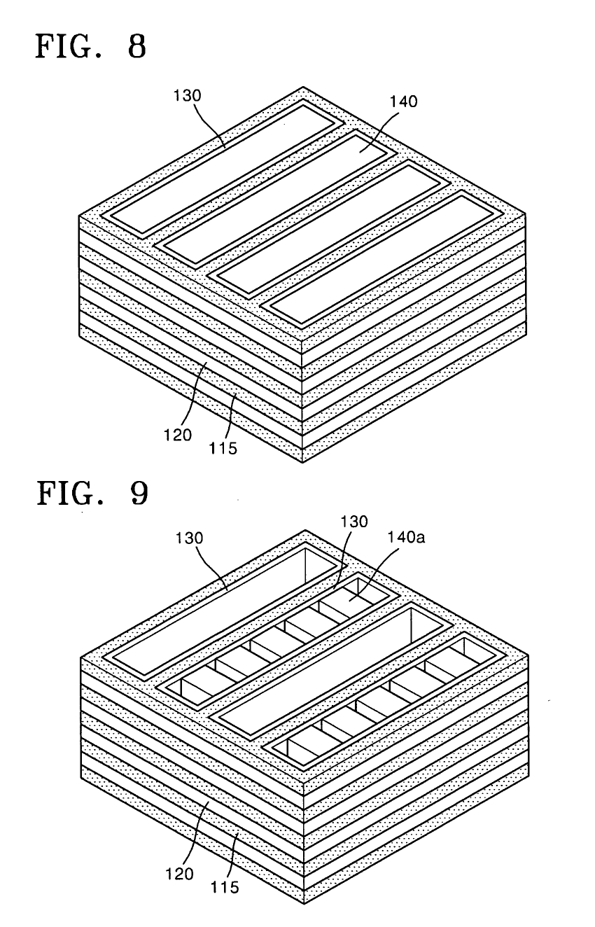

Referring to FIG. 8, a second electrode layer 140 may be formed on the data storage layers 130 to fill the trenches 125. For example, the second electrode layer 140 may be formed by depositing a second type of conductive semiconductor using, for example, a chemical vapour deposition process and planarizing the semiconductor layer. For example, the second electrode layer 140 may be formed as an epitaxial layer of poly-silicon, and may be doped with second conductive impurities having properties opposite that of the first electrode layers 115. The planarization may, for example, be carried out by using an etchback or chemical-mechanical polishing (CMP) method.

Referring to FIG. 9, the second electrode layer 140 may, for example, be patterned using a photolithography process followed by an etch process, to form a plurality of the vertical electrodes 140a. The vertical electrodes 140a may remain within odd rows or even rows of the trenches 125. Accordingly, as shown in FIG. 10, the vertical electrodes 140a may be interposed between the first sidewalls 112a and the third sidewalls 112b, and may not be interposed between the second sidewalls 113a and the fourth sidewalls 113b. However, the arrangement is merely an example, and example embodiments are not limited thereto.

Referring to FIG. 10, each of the first electrode layers 115 may be cut to define the first and second horizontal electrodes 115a and 115b and the first and second wordlines 117a and 117b. The first wordline 117a may be connected to the first horizontal electrodes 115a and may be separated from the second horizontal electrodes 115b. The second wordline 117b may be connected to the second horizontal electrodes 115b and may be separated from the first horizontal electrodes 115a.

For example, the structure of FIG. 10 may be formed by performing a cutting operation on the structure of FIG. 9 using a photolithography process followed by an etch process; for example, cutting between the first horizontal electrodes 115a and the second wordline 117b and cutting between the second horizontal electrodes 115b and the first wordline 117a.

According to the fabricating method of example embodiments, memory cells in a stacked layer structure may be formed simultaneously. Therefore, the fabricating method may reduce fabrication cost by simplifying the fabrication operations.

Example embodiments will be described with reference to FIGS. 4-13, with FIGS. 11-13 showing a method of fabricating the non-volatile memory device of FIG. 4. Detailed descriptions of FIGS. 4-10 were previously given and will not be repeated. The fabricating method according to example embodiments may be a modification of the fabricating method shown in FIGS. 5 through 10. For example, a fabricating operation shown in FIG. 11 may be performed following the fabricating operations shown in FIGS. 5 and 6.

Referring to FIG. 11, the data storage layers 130a may be formed to fill the trenches 125. The data storage layers 130a may be formed by forming a material of, for example, a fuse or an anti-fuse using, for example, a chemical vapour deposition process. The data storage layers 130a may be planarized using a planarizing process using, for example, an etchback or a CMP process.

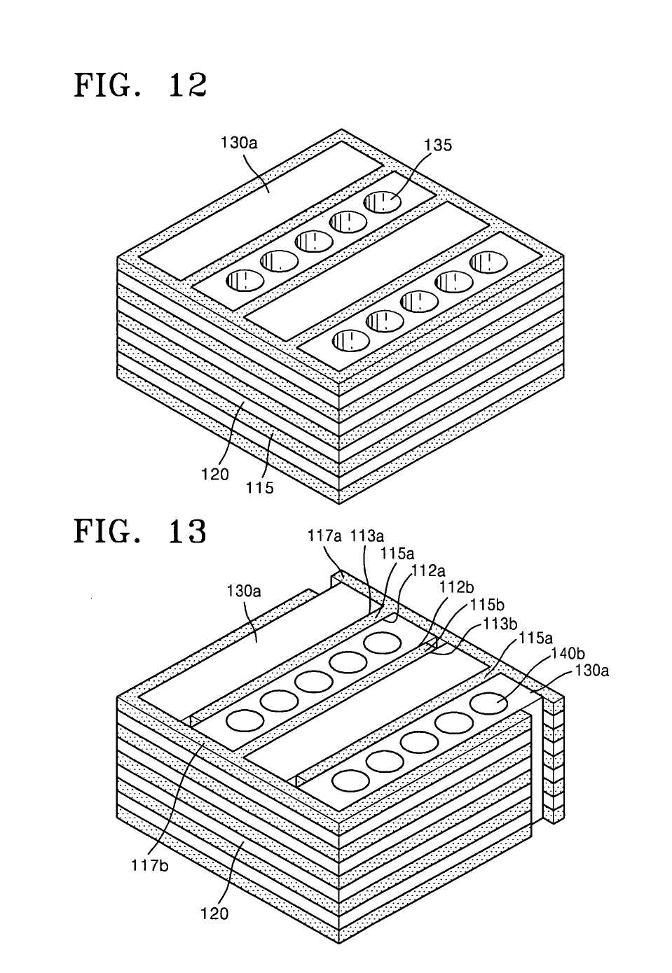

Referring to FIG. 12, a plurality of holes 135 may be formed in the data storage layers 130a. The holes 135 may be formed in odd rows or even rows of the data storage layers 130a using, for example, a photolithography process followed by an etching process to form the holes 135. However, the arrangement is merely an example, and example embodiments are not limited thereto.

Referring to FIGS. 12 and 13, vertical electrodes 140b may be buried correspondingly in the holes 135. The vertical electrodes 140b may be formed by forming a second electrode layer using, for example, a chemical vapour deposition process. The vertical electrodes 140b may be planarized using a planarization process. The vertical electrodes 140b may be formed of, for example, a second conductive semiconductor material.

Each of the first electrode layers 115 may be cut to define the first and second horizontal electrodes 115a and 115b and the first and second wordlines 117a and 117b. The first wordlines 117a may be connected to the first horizontal electrodes 115a and may be separated from the second horizontal electrodes 115b. The second wordlines 117b may be connected to the second horizontal electrodes 115b and may be separated from the first horizontal electrodes 115a.

While example embodiments have been particularly shown and described, it will be understood by one of ordinary skill in the art that variations in form and detail may be made therein without departing from the spirit and scope of the claims.

What is claimed is:

1. A non-volatile memory device comprising:
at least one first horizontal electrode having a first sidewall and a second sidewall;
at least one second horizontal electrode having a third sidewall and a fourth sidewall, wherein the third sidewall faces the first sidewall;
at least one vertical electrode between the first sidewall and the third sidewall, intersecting each of the at least one first and the at least one second horizontal electrodes; and
at least one data storage layer between the at least one first horizontal electrode and the at least one vertical electrode and between the at least one second horizontal electrode and the at least one vertical electrode, the data storage layers being capable of locally storing a change of electrical resistance.

2. The non-volatile memory device of claim 1, wherein the at least one vertical electrode crosses each of the at least one first and at least one second horizontal electrodes.

3. The non-volatile memory device of claim 1, wherein the at least one vertical electrode comprises a plurality of vertical electrodes disposed apart from each other and the at least one data storage layer correspondingly fills the areas around the plurality of vertical electrodes.

4. The non-volatile memory device of claim 1, wherein the at least one first horizontal electrode and the at least one second horizontal electrode are parallel to each other and the at least one vertical electrode is perpendicular to an extending direction of the at least one first and at least one second horizontal electrodes.

5. The non-volatile memory device of claim 1, wherein the shape of the at least one vertical electrode may be a cylinder or a polygon-pillar.

6. The non-volatile memory device of claim 1, wherein the at least one data storage layer comprises one of a fuse and an anti-fuse.

7. The non-volatile memory device of claim 1, wherein the at least one first and the at least one second horizontal electrodes comprise a first conductive semiconductor, and the at least one vertical electrode comprises a second conductive semiconductor being an opposite conductive type from the first conductive semiconductor.

8. The non-volatile memory device of claim 1, wherein the at least one first horizontal electrode comprises a plurality of first horizontal electrodes, the at least one second horizontal electrode comprises a plurality of second horizontal electrodes alternating with the first horizontal electrodes, and where the at least one vertical electrode comprises a plurality of vertical electrodes in a plurality of rows between the first sidewalls of the plurality of the first horizontal electrodes and the third sidewalls of the plurality of the second horizontal electrodes.

9. The non-volatile memory device of claim 8, wherein the plurality of vertical electrodes are not interposed in the rows between the second sidewalls of the plurality of first horizontal electrodes and the fourth sidewalls of the plurality of the second horizontal electrode.

10. The non-volatile memory device of claim 8, further comprising:
at least one first wordline electrically connected to at least one of the plurality of the first horizontal electrodes; and
at least one second wordline electrically connected to at least one of the plurality of second horizontal electrodes.

11. The non-volatile memory device of claim 10, wherein the at least one first wordline is connected to one end of each of the plurality of first horizontal electrodes, and the at least one second wordline is connected to one end of each of the plurality of second horizontal electrodes and is on a side opposite to the at least one first wordline.

12. The non-volatile memory device of claim 1, wherein the at least one first horizontal electrode comprise a plurality of first horizontal electrodes stacked in a plurality of layers, and the at least one second horizontal electrode comprises a plurality of second horizontal electrodes stacked in a plurality of layers facing the plurality of first horizontal electrodes.

13. The non-volatile memory device of claim 12, wherein the at least one vertical electrode extends vertically across the plurality of first and second horizontal electrodes.

14. The non-volatile memory device of claim 12, wherein the at least one data storage layer extends vertically across the plurality of first and second horizontal electrodes.
